(19) United States
(12) Patent Application Publication
(10) Pub. No.: US 2024/0405758 A1
(43) Pub. Date: Dec. 5, 2024

(54) Quantum Control Play Table-Based Wave Player

(71) Applicant: International Business Machines Corporation, Armonk, NY (US)

(72) Inventors: Scott M. WILLENBORG, Stewartville, MN (US); Jeremy T EKMAN, West Concord, MN (US); Jeffrey Joseph RUEDINGER, Rochester, MN (US); Brian Thomas VANDERPOOL, Byron, MN (US)

(21) Appl. No.: 18/326,164

(22) Filed: May 31, 2023

(51) Int. Cl. H03K 3/38; G06N 10/40

(52) U.S. Cl. CPC H03K 3/38; G06N 10/40

(57) ABSTRACT

One or more systems, devices, computer program products and/or computer-implemented methods of use provided herein relate to a process to rapidly generate waveforms for quantum operations, the process employing separation of waveform software control from waveform generation control. An exemplary wave player system can comprise a waveform generator, a memory associated with the waveform generator, wherein the memory stores a waveform play table comprising a plurality of play table entries having a plurality of waveform definition aspects that comprise, or direct to, a plurality of parameters that define a plurality of waveforms, and a processing unit associated with the waveform generator, wherein the processing unit accesses a first play table entry, of the plurality of play table entries, comprising a first waveform definition aspect, of the plurality of waveform definition aspects, based on an instruction obtained at the processing unit.

### TECHNICAL FIELD

The present disclosure relates to rapidly and efficiently generating waveforms for operation of one or more qubits of a quantum system, and more specifically to separation of waveform software control from waveform generation control for generating the waveforms.

### BACKGROUND

In quantum computing systems, waveform generation refers to the generation of a wave, pulse, signal and/or the like having one or more determined parameters of frequency, phase, envelope, duration or amplitude. The generated waveform is directed at qubit hardware to enable excitation state change and/or parameter measurement of one or more qubits of a quantum processor to thereby operate one or more quantum gates of a determined quantum circuit.

### SUMMARY

The following presents a summary to provide a basic understanding of one or more embodiments described herein. This summary is not intended to identify key or critical elements, and/or to delineate scope of particular embodiments or scope of claims. Its sole purpose is to present concepts in a simplified form as a prelude to the more detailed description that is presented later. In one or more embodiments described herein, systems, computer-implemented methods, apparatuses and/or computer program products can provide a process to allow for rapid and efficient generation of waveforms, such as during quantum logic circuit operation at a quantum processor.

In accordance with an embodiment, an exemplary wave player system can comprise a waveform generator, a memory associated with the waveform generator, wherein the memory stores a waveform play table comprising a plurality of play table entries having a plurality of waveform definition aspects that comprise, or direct to, a plurality of parameters that define a plurality of waveforms, and a processing unit associated with the waveform generator, wherein the processing unit accesses a first play table entry, of the plurality of play table entries, comprising a first waveform definition aspect, of the plurality of waveform definition aspects, based on an instruction obtained at the processing unit.

In accordance with another embodiment, a computer-implemented method can comprise storing, by a system operatively coupled to the processor, at a memory associated with a waveform generator, a waveform play table comprising a plurality of play table entries having a plurality of waveform definition aspects that comprise, or direct to, a plurality of parameters that define a plurality of waveforms, and accessing, by a processing unit of the system that is associated with the waveform generator a first play table entry, of the plurality of play table entries, comprising a first waveform definition aspect, of the plurality of waveform definition aspects, based on an instruction obtained at the processing unit.

In accordance with yet another embodiment, a computer program product facilitating a process to generate a waveform comprises a computer readable storage medium having program instructions embodied therewith, the program instructions executable by a processor to cause the processor to store, by the processor, at a memory associated with a waveform generator, a waveform play table comprising a plurality of play table entries having a plurality of waveform definition aspects that comprise, or direct to, a plurality of parameters that define a plurality of waveforms, and access, by an additional processing unit of the system, that is associated with the waveform generator a first play table entry, of the plurality of play table entries, comprising a first waveform definition aspect, of the plurality of waveform definition aspects, based on an instruction obtained at the processing unit.

An advantage of any one or more of the above-indicated embodiments can be, relative to a cryogenic-based waveform generator, performance of overhead, including waveform parameter definition and/or quantum circuit waveform instruction, majoratively using hardware/software disposed external to the cryogenic environment of a quantum device. In this way, reduced data generation and data transfer can be provided within the cryogenic environment, based on use of loaded waveform definition aspects at a memory that is cryogenically disposed and associated with the waveform generator. This further can result in reduced power requirement and reduced heat generation within the cryogenic environment, such as by a corresponding processing unit disposed within the cryogenic environment and associated with the waveform generator.

Another advantage of the above-indicated embodiments can be separation of waveform software control from waveform generation control for generating the waveforms. This can allow for reduced data necessary to be transmitted into a cryogenic environment to the waveform generator to cause generation of a waveform during quantum circuit operation. That is, loading of the memory associated with the waveform generator with waveform definition aspects can be performed separate from quantum circuit operation.

Subsequently, during quantum circuit operation, overhead of setting parameters between waveform generations can be performed external to the cryogenic environment absent transfer of any, or at least of large quantities of, data into the cryogenic environment for the parameter determination. As a result, waveform generation in the cryogenic environment can be based on low-data-volume instructions transmitted from a software controller external to the cryogenic environment to the processor associated with the waveform generator, while employing the loaded waveform definition aspects. That is, the reduced instruction transmission time correlates with reduced quantum gate operation times available in the currently rapidly evolving domain of quantum device operation. This further can result in, relative to a quantum application, operation of an increased number of shots (e.g., quantum circuit executions) within a given time defining qubit coherency for those one or more qubits of the quantum being employed (e.g., being operated upon by the waveform generator). That is, gap-time between waveform generations can be limited and/or altogether eliminated.

In one or more embodiments of the above-indicated system, computer-implemented method and/or computer program product, an instruction component of a control subsystem generates the instruction, and a transmitting component of the control subsystem transmits the instruction along a communication line communicatively connecting the control subsystem and a wave player subsystem comprising the waveform generator and the memory and processing unit associated with the waveform generator.

In one more embodiments of the above-indicated system, computer-implemented method and/or computer program product, the processing unit, the memory and at least a portion of the waveform generator are disposed within a cryogenic environment, and the instruction component is disposed external to the cryogenic environment.

An advantage of this feature can be, relative to a cryogenic-based waveform generator, performance of overhead, including waveform parameter definition and/or quantum circuit waveform instruction, majoratively using hardware/software disposed external to the cryogenic environment of a quantum device. In this way, reduced data generation and data transfer can be provided within the cryogenic environment, based on use of loaded waveform definition aspects at the memory that is cryogenically disposed and associated with the waveform generator. This further can result in reduced power requirement and reduced heat generation within the cryogenic environment, such as by a corresponding processor disposed within the cryogenic environment and associated with the waveform generator.

### DESCRIPTION OF THE DRAWINGS

FIG. 1 illustrates a block diagram of an example, non-limiting quantum system that can operate on one or more qubits, in accordance with one or more embodiments described herein.

FIG. 2 illustrates a block diagram of another example, non-limiting system, comprising the quantum system of FIG. 1 and a waveform instruction system, in accordance with one or more embodiments described herein.

FIG. 3 illustrates a visual representation of a play table that can be employed by the non-limiting system of FIG. 2, in accordance with one or more embodiments described herein.

FIG. 4 illustrates a visual representation of a playlist that can be employed by the non-limiting system of FIG. 2, in accordance with one or more embodiments described herein.

FIG. 5 provides a schematic illustration of a cryostat of the quantum system of FIG. 1, in accordance with one or more embodiments described herein.

FIG. 6 illustrates an exemplary waveform generation sequence code of an instruction for use by the non-limiting system of FIG. 2, in accordance with one or more embodiments described herein.

FIG. 7 illustrates a process flow for preparing a wave player subsystem of the non-limiting system of FIG. 2, in accordance with one or more embodiments described herein.

FIG. 8 illustrates a process flow for preparing a wave player subsystem of the non-limiting system of FIG. 2, in accordance with one or more embodiments described herein.

FIG. 9 illustrates a continuation of the process flow of FIG. 8 for generating one or more waveforms for operating on one or more qubits of the non-limiting system of FIG. 2, in accordance with one or more embodiments described herein.

FIG. 10 illustrates a block diagram of example, non-limiting, computer environment in accordance with one or more embodiments described herein.

### DETAILED DESCRIPTION

The following detailed description is merely illustrative and is not intended to limit embodiments and/or application or utilization of embodiments. Furthermore, there is no intention to be bound by any expressed or implied information presented in the preceding Summary section, or in the Detailed Description section. One or more embodiments are now described with reference to the drawings, wherein like reference numerals are utilized to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Discussion is provided herein relative to a configuration of a hybrid system comprising a classical system and a quantum system, the quantum system comprising a cryostat or other cryogenic environment-providing sub-system. One or more processes can be employed at the quantum system for lowering components with the cryogenic environment to extremely low temperatures, such as mK temperatures.

It is noted that the embodiments described herein thus also can have use in the nuclear magnetic resonance field or ion cyclotron field, among other cryogenic environment-employing uses. Description and discussion herein are therefore not limited to use with a quantum system or in the quantum domain only.

Further, it is noted that the embodiments described herein can have use in fields absent employment with a cryogenic environment. Indeed, the frameworks discussed herein are applicable more generally to separation of waveform software control from waveform generation control for generating waveforms, regardless of an environment of the waveform generation control.

In one or more embodiments described herein, a waveform generator of a quantum system, such as providing both for control and readout pulse generation, can be at least partially disposed within a cryogenic environment, such as of a cryostat. This can allow for generation of a wave (e.g., pulse, wave, waveform, signal) to affect one or more qubits also disposed within the cryogenic environment. In this way, transmission of and contact of the waveform with the one or more qubits can be relatively immediate due to local disposition of the waveform generator relative to the qubit hardware. This is as compared to location of the waveform generator external to the cryogenic environment, which external location necessitates longer transmission of the waveform.

In existing systems, generation of waveforms can be by various approaches and/or implementations of quantum control electronics that are directed towards reduction of memory usage. For example, full definition of a pulse in waveform memory is a common method, though it can be expensive to fully define the full waveform in limited field programmable gate array (FPGA) memory hardware. As used herein, “expense” and/or “cost” can refer to one or more of time, power, memory, general software overhead and/or heat generated.

Another approach to reduce memory usage can direct software, such as controlled by a microprocessor, to specify just a waveform envelope (e.g., outlining the waveform) in memory and then use hardware such as a numerically controlled oscillator (NCO) to generate the sinusoidal waveform defined by the waveform envelope. Software can specify the frequency, phase, amplitude, duration, offset and envelope information as parameters to the NCO wave generation logic, providing software parameterized waveform generation capability.

However, parameterized waveform generation employs a high software overhead for changing parameters of the waveform, especially when implementing back-to-back waveforms, shorter waveforms and/or waveforms for dynamic gate applications. This is at least because, as qubit technologies have improved, qubit gate times have reduced leaving minimal time between individual waveform generation operations to setup the next waveform generation. For example, current gate times can be in the range of about 10 ns to about 15 ns.

For example, consider a quantum room temperature control electronics system running at a typical frequency of 250 MHz and having a set of 32-bit general purpose registers. Consider the following sample code segment:
ADD1 R1, R0, #FREQUENCY1//set frequency
ADD1 R2, R0, #PHASE1//set phase
ADD1 R3, R0, #AMPLITUDE1//set amplitude
ADD1 R4, R0, #ENVELOPE1//set waveform envelope starting location
ADD1 R5, R0, #DURATION1//set length of waveform to play
PW R1, R2, R3, R4, R5//play wave #1 using parameters in R1/R2/R3/R4/R5
ADD1 R1, R0, #FREQUENCY2//set frequency
ADD1 R2, R0, #PHASE2//set phase
ADD1 R3, R0, #AMPLITUDE2//set amplitude
ADD1 R4, R0. #ENVELOPE2//set waveform envelope starting location
ADD1 R5, R0, #DURATION2//set length of waveform to play
PW R1, R2, R3, R4. R5//play wave #2 using parameters in R1/R2/R3/R4/R5

In the above exemplary instruction sequence, there are a minimum of five instructions between play wave instructions, and there also could be many more depending on a complexity of determining the frequency, phase, amplitude and/or envelope values (e.g., waveform parameters). However, even with only five instructions, an instruction engine operating at 250 MHz would need approximately 20 ns or more time between waveform generations to generate the next waveform. Given qubit gate times that can be in the 10-15 ns range, it can be impossible to have gapless back-to-back waves in view of such conventional waveform generation framework. As a result, when a gap in waveform generations occurs due to instructions not having yet been received for a subsequent waveform generation, the waveform generator can instead issue a constant tone, such as to remain ready. However, issuance of such constant tone can cause loss of control of the stream of signals being transmitted to the qubit hardware.

Accordingly, to account for this deficiency, and/or one or more other deficiencies of conventional waveform generation frameworks, one or more embodiments described herein are directed to a waveform generation framework that can generally issue a playwave instruction to a waveform generation hardware without continual reload of the playwave instruction and/or of parameters thereof. This framework can allow for rapid playwave instruction generation (e.g., instruction for generating a waveform) within a time range equal to or smaller than about 10 ns to about 15 ns. The framework further can account for override of one or more parameters already instructed, issuance of mid-circuit instructions, such as related to a dynamic circuit, and/or issuance of a set of instructions for generating a set of one or more waveforms, each again within a time range equal to or smaller than about 10 ns to about 15 ns.

For example, issuance of such instruction, using the one or more embodiments described herein can allow for about 4 bits to about 10 bits of information to be sent to a respective waveform subsystem to direct the recall of the one or more waveform definition aspects for a quantum gate execution. Differently, using existing techniques, a full waveform instruction being sent to the waveform subsystem between waveform generations can account for at least 100 bits to 150 bits of information.

Furthermore, one or more embodiments described herein can account for this rapid playwave instruction issuance with reduced power consumption, and thus reduced heat generation, within a related cryogenic environment. This can be due to, at least in part, separation of instruction generation and waveform generation, where instruction generation can be performed external to a cryogenic environment, instructions transmitted into the cryogenic environment, and the waveform generation performed within the cryogenic environment. The waveform generation can exhibit relatively low power, time, software overhead and memory cost within the cryogenic environment due to loading of one or more waveform definition aspects to a storage that is disposed local to the waveform generator, e.g., within the cryogenic environment. Differently, cost to calculate parameters, perform waveform parameterization, transmit instructions separate from a waveform generation/shot execution and/or load the storage, e.g., time, power, software overhead and/or memory, can be higher than that employed during instruction issuance and waveform generation immediately in correspondence with a waveform generation/shot execution.

Accordingly, in one or more embodiments described herein, due to the cryogenic environment-based storage of waveform definition aspects, there can be a reduction in the amount of information that is communicated between an instruction execution engine, perhaps at room temperature or other temperature lower than that of the immediate environment of the waveform generator, and the waveform generator. This can in turn allow for storage of what is referred to herein as a particular type of play table being a playlist. A playlist can comprise waveform definition aspects and/or instructions for generating more than one waveform, such as a sequence of waveforms, or even multiple repeating sequences of waveforms. This can be useful when running plural shots in sequence at a quantum device and/or for quantum calibration purposes, such as of a quantum circuit, quantum gate and/or parameter thereof.

As used herein, the term “waveform definition aspect” can refer to a parameter, call function, static or non-static function call, or other data/metadata employed the waveform generator or by a processing unit associated with the waveform generator to generate one or more waveforms.

Discussion now turns herein to one or more exemplary embodiments described in particular relative to use in a quantum device for operation of a quantum circuit. As used herein, a quantum circuit can be a set of operations, such as for executing one or more gates, performed on a set of real-world physical qubits with the purpose of obtaining one or more qubit measurements. A quantum processor can comprise the one or more real-world physical qubits.

Qubit states only can exist (or can only be coherent) for a limited amount of time. Thus, an objective of operation of a quantum logic circuit (e.g., including one or more qubits) can be to maximize the utilization of the coherence time of the employed qubits. Time spent to operate the quantum logic circuit can undesirably reduce the available time of operation on one or more qubits. This can be due to the available coherence time of the one or more qubits prior to decoherence of the one or more qubits. For example, a qubit state can be lost in less than 100 to 200 microseconds in one or more cases.

Operation of the quantum circuit can be supported, such as by a pulse component (also herein referred to as a waveform generator), to produce one or more physical pulses and/or other waveforms, signals and/or frequencies to alter one or more states of one or more of the physical qubits. The altered states can be measured, thus allowing for one or more computations to be performed regarding the qubits and/or the respective altered states.

Operations on qubits generally can introduce some error, such as some level of decoherence and/or some level of quantum noise, further affecting qubit availability. Quantum noise can refer to noise attributable to the discrete and/or probabilistic natures of quantum interactions.

Initializing qubits to a known state can be a standard element of universal quantum computation. The initialization typically can employ a qubit measurement followed by an operation conditional on the measurement outcome. This initialization scheme can be limited by the measurement fidelity and can be improved by running the measurement and reset operations more than once. Using the framework herein, this type of initialization can be performed with low-data-volume transmission into the cryogenic environment to the waveform generator and using low-power and low-memory consumption within the cryogenic environment by the waveform generator.

One or more embodiments are now described with reference to the drawings, where like referenced numerals are used to refer to like elements throughout. As used herein, the terms “entity”, “requesting entity” and “user entity” can refer to a machine, device, component, hardware, software, smart device and/or human.

In the following description, for purposes of explanation, numerous specific details are set forth in order to provide a more thorough understanding of the one or more embodiments. It is evident, however, in various cases, that the one or more embodiments can be practiced without these specific details.

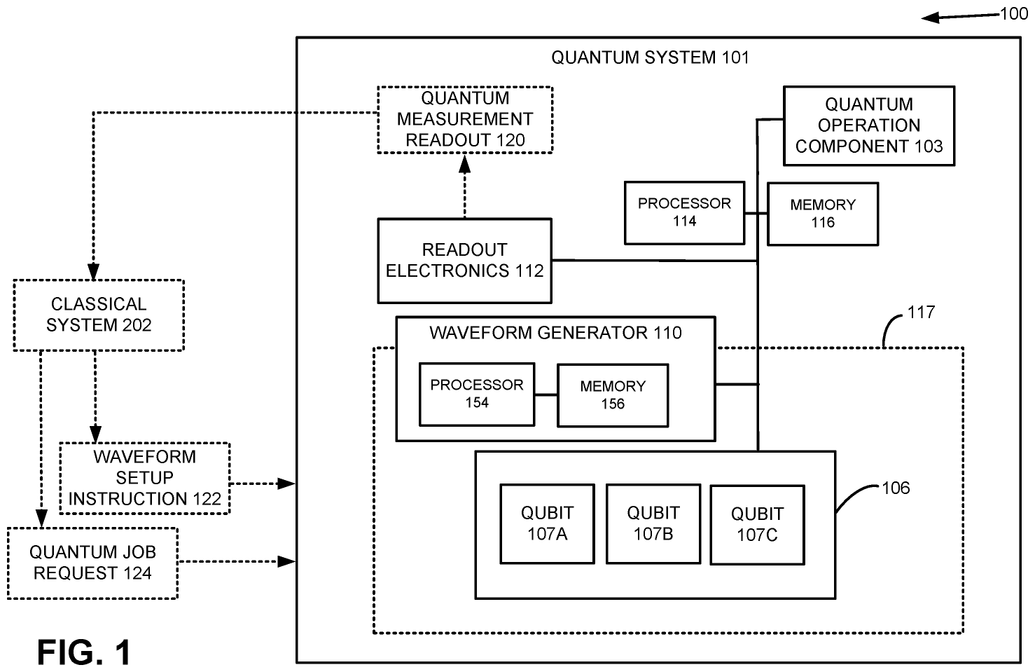

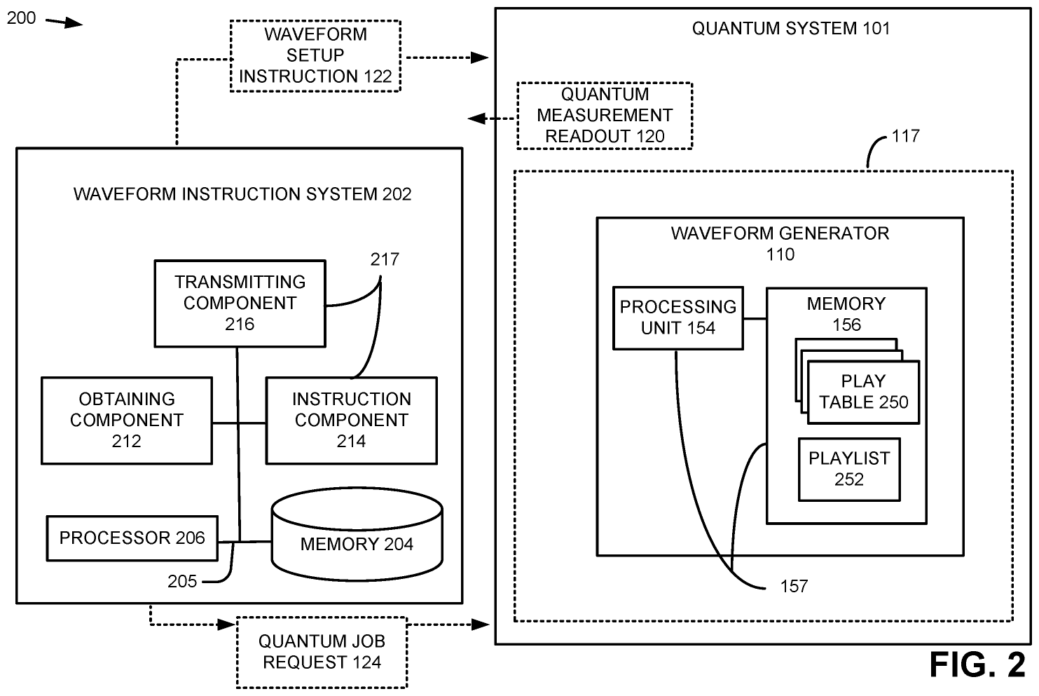

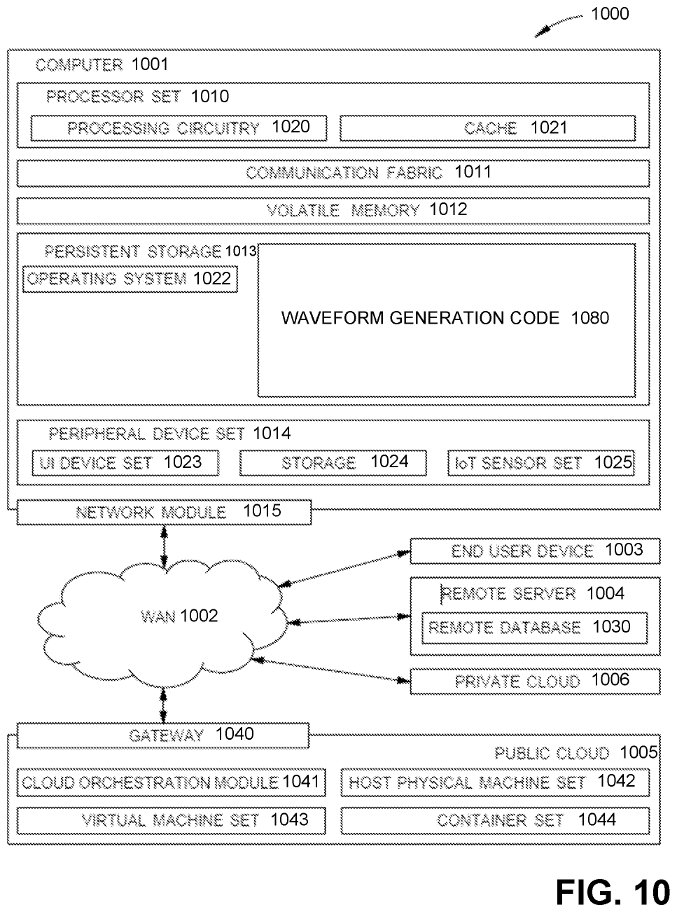

Further, the embodiments depicted in one or more figures described herein are for illustration only, and as such, the architecture of embodiments is not limited to the systems, devices and/or components depicted therein, nor to any particular order, connection and/or coupling of systems, devices and/or components depicted therein. For example, in one or more embodiments, the non-limiting systems described herein, such as non-limiting systems 100 and/or 200 as illustrated at FIGS. 1 and 2, and/or systems thereof, can further comprise, be associated with and/or be coupled to one or more computer and/or computing-based elements described herein with reference to an operating environment, such as the computing environment 1000 illustrated at FIG. 10. In one or more described embodiments, computer and/or computing-based elements can be used in connection with implementing one or more of the systems, devices, components and/or computer-implemented operations shown and/or described in connection with FIGS. 1 and/or 2 and/or with other figures described herein.

Turning first generally to FIG. 1, one or more embodiments described herein can include one or more devices, systems and/or apparatuses that can provide a process to generate one or more waveforms for a quantum-based operation (e.g., using a quantum device), such as for operating one or more qubits of a quantum device. Accordingly, at FIG. 1, illustrated is a block diagram of an example, non-limiting system 100 that can at least partially facilitate such a process. While referring here to one or more processes, facilitations and/or uses of the non-limiting system 100, description provided herein, both above and below, also can be relevant to one or more other non-limiting systems described herein, such as the non-limiting system 200, to be described below in detail.

As illustrated at FIG. 1, the non-limiting system 100 can comprise a quantum system 101 that can be employed with a classical system 202.

Generally, the quantum system 101 (e.g., quantum computer system, superconducting quantum computer system and/or the like) can employ quantum algorithms and/or quantum circuitry, including computing components and/or devices, to perform quantum operations and/or functions on input data to produce results that can be output to an entity. The quantum circuitry can comprise quantum bits (qubits), such as multi-bit qubits, physical circuit level components, high level components and/or functions. The quantum circuitry can comprise physical pulses that can be structured (e.g., arranged and/or designed) to perform desired quantum functions and/or computations on data (e.g., input data and/or intermediate data derived from input data) to produce one or more quantum results as an output. The quantum results, e.g., quantum measurement readout 120, can be responsive to the quantum job request 124 and associated input data and can be based at least in part on the input data, quantum functions and/or quantum computations.

In one or more embodiments, the quantum system 101 can comprise components, such as a quantum operation component 103, a quantum processor 106, pulse component 110 (e.g., a waveform generator) and/or a readout electronics 112. In one or more other embodiments, the readout electronics 112 can be comprised at least partially by the classical system 202 and/or be external to the quantum system 101. The quantum processor 106 can comprise one or more, such as plural, qubits 107. Individual qubits 107A, 107B and 107C, for example, can be fixed frequency and/or single junction qubits, such as transmon qubits.

The quantum processor 106 can be any suitable processor. The quantum processor 106 can generate one or more instructions for controlling the one or more processes of the quantum operation component 103.

The quantum operation component 103 can obtain (e.g., download, receive, search for and/or the like) a quantum job request 124 requesting execution of one or more quantum programs and/or a physical qubit layout. The quantum job request 124 can be provided in any suitable format, such as a text format, binary format and/or another suitable format. In one or more embodiments, the quantum job request 124 can be obtained by a component other than of the quantum system 101, such as a by a component of the classical system 102.

In one or more embodiments, a memory 116 and/or processor 114 can be associated with the quantum operation component 103, where suitable.

The quantum operation component 103 can determine mapping of one or more quantum logic circuits for executing a quantum program. In one or more embodiments, the quantum operation component 103 and/or quantum processor 106 can direct the waveform generator 110 to generate one or more pulses, tones, waveforms and/or the like to affect one or more qubits 107, such as in response to a quantum job request 124.

The waveform generator 110 can generally cause the quantum processor 106 to perform one or more quantum processes, calculations and/or measurements by creating a suitable electro-magnetic signal. For example, the waveform generator 110 can operate one or more qubit effectors, such as qubit oscillators, harmonic oscillators, pulse generators and/or the like to cause one or more pulses to stimulate and/or manipulate the state(s) of the one or more qubits 107 comprised by the quantum system 101.

In one or more embodiments a separate processing unit 154 (e.g., processor) and memory 156 can be associated with the waveform generator 110. The memory 156 can comprise a storage (e.g., SRAM) for one or more waveform definition aspects in any suitable format, such as a table, log, registry, matrix, list and/or other format. The processing unit 154 can be configured to access the memory 156, such as using one or more call functions or other suitable means in response to receipt of one or more quantum job requests 124 and/or waveform setup instructions 122. Access can comprise read and/or write access (e.g., read access in response to a quantum job request 124 or write access in response to a waveform setup instruction 122). In one or more embodiments, the processing unit 154 can comprise a programmable CPU, programmed for accessing the memory 156 in response to receipt of one or more quantum job requests 124 and/or waveform setup instructions 122.

The quantum processor 106 and a portion or all of the waveform generator 110 can be contained in a cryogenic environment, such as generated by a cryogenic environment 117, such as effected by a dilution refrigerator. Indeed, a signal can be generated by the waveform generator 110 to affect one or more of the plurality of qubits 107. Where the plurality of qubits 107 are superconducting qubits, cryogenic temperatures, such as about 4K or lower, can be employed for function of these physical qubits. Accordingly, one or more elements of the readout electronics 113 also can be constructed to perform at such cryogenic temperatures.

The readout electronics 113, or at least a portion thereof, can be contained in the cryogenic environment 117, such as for reading a state, frequency and/or other characteristic of qubit, excited, decaying or otherwise.

Further, the aforementioned description(s) refer(s) to the operation of a single set of instructions run on a single qubit. However, scaling can be achieved. For example, instructions can be calculated, transmitted, employed and/or otherwise used relative to one or more qubits (e.g., non-neighbor qubits) in parallel with one another, one or more quantum circuits in parallel with one another, and/or one or more qubit mappings in parallel with one another.

Turning next to FIG. 2, but also still referring to FIG. 1, the non-limiting system 200 can be a hybrid system and thus can include both a quantum system and a classical system, such as the quantum system 101 and the classical-based system 102 (also herein referred to as a classical system 202). In one or more other embodiments, the quantum system 101 can be separate from, but function in combination with, the classical system 202. In one or more embodiments, one or more components of the quantum system 101, such as the readout electronics 112, can be at least partially comprised by the classical system 202, or otherwise comprised external to the quantum system 101. In one or more embodiments, one or more components of the classical system 202 can be at least partially comprised by the quantum system 101, or otherwise comprised external to the classical system 202.

One or more communications between one or more components of the non-limiting system 200 can be provided by wired and/or wireless means including, but not limited to, employing a cellular network, a wide area network (WAN) (e.g., the Internet), and/or a local area network (LAN). Suitable wired or wireless technologies for supporting the communications can include, without being limited to, wireless fidelity (Wi-Fi), global system for mobile communications (GSM), universal mobile telecommunications system (UMTS), worldwide interoperability for microwave access (WiMAX), enhanced general packet radio service (enhanced GPRS), third generation partnership project (3GPP) long term evolution (LTE), third generation partnership project 2 (3GPP2) ultra-mobile broadband (UMB), high speed packet access (HSPA), Zigbee and other 802.XX wireless technologies and/or legacy telecommunication technologies, BLUETOOTH®, Session Initiation Protocol (SIP), ZIGBEE®, RF4CE protocol, WirelessHART protocol, 6LoWPAN (Ipv6 over Low power Wireless Area Networks), Z-Wave, an ANT, an ultra-wideband (UWB) standard protocol and/or other proprietary and/or non-proprietary communication protocols.

The classical system 202 and/or the quantum system 101 can be associated with, such as accessible via, a cloud computing environment such that aspects of classical processing can be distributed between the classical system 202 and the cloud computing environment.

Next, discussion turns to operations of the classical system 202 that can be performed to facilitate waveform instruction for use by the waveform generator 110 of the quantum system 101.

Generally, the classical system 202 can comprise any suitable type of component, machine, device, facility, apparatus and/or instrument that comprises a processor and/or can be capable of effective and/or operative communication with a wired and/or wireless network. All such embodiments are envisioned. For example, the classical system 202 can comprise a server device, computing device, general-purpose computer, special-purpose computer, quantum computing device (e.g., a quantum computer), tablet computing device, handheld device, server class computing machine and/or database, laptop computer, notebook computer, desktop computer, cell phone, smart phone, consumer appliance and/or instrumentation, industrial and/or commercial device, digital assistant, multimedia Internet enabled phone, multimedia players and/or another type of device and/or computing device. Likewise, the classical system 202 can be disposed and/or run at any suitable device, such as, but not limited to a server device, computing device, general-purpose computer, special-purpose computer, quantum computing device (e.g., a quantum computer), tablet computing device, handheld device, server class computing machine and/or database, laptop computer, notebook computer, desktop computer, cell phone, smart phone, consumer appliance and/or instrumentation, industrial and/or commercial device, digital assistant, multimedia Internet enabled phone, multimedia players and/or another type of device and/or computing device.

The classical system, e.g., a waveform instruction system 202, can comprise one or more components, such as a memory 204, quantum processor 206, bus 205, obtaining component 212, instruction component 214 and/or transmitting component 216. Generally, the waveform instruction system 202 can perform one or more operations to facilitate waveform generation by the waveform generator 110 of the quantum system 101. It is noted that use of the waveform instruction system 202 can be provided in an environment absent a quantum system 101, such as for other use, and thus can be more generally described as performing one or more operations to facilitate waveform generation by a waveform generator of a corresponding system. Although, discussion herein now turns specifically to examples related to use with a quantum device, e.g., comprising and/or comprised by the quantum system 101.

Discussion first turns briefly to the processor 206, memory 204 and bus 205 of the waveform instruction system 202. For example, in one or more embodiments, the classical system 202 can comprise the processor 206 (e.g., computer processing unit, microprocessor, classical processor, quantum processor and/or like processor). In one or more embodiments, a component associated with the waveform instruction system 202, as described herein with or without reference to the one or more figures of the one or more embodiments, can comprise one or more computer and/or machine readable, writable and/or executable components and/or instructions that can be executed by processor 206 to provide performance of one or more processes defined by such component(s) and/or instruction(s). In one or more embodiments, the processor 206 can comprise the obtaining component 212, instruction component 214 and/or transmitting component 216.

In one or more embodiments, the waveform instruction system 202 can comprise the computer-readable memory 204 that can be operably connected to the processor 206. The memory 204 can store computer-executable instructions that, upon execution by the processor 206, can cause the processor 206 and/or one or more other components of the waveform instruction system 202 (e.g., obtaining component 212, instruction component 214 and/or transmitting component 216) to perform one or more actions. In one or more embodiments, the memory 234 can store computer-executable components (e.g., obtaining component 212, instruction component 214 and/or transmitting component 216).

The waveform instruction system 202 and/or a component thereof as described herein, can be communicatively, electrically, operatively, optically and/or otherwise coupled to one another via a bus 205. Bus 205 can comprise one or more of a memory bus, memory controller, peripheral bus, external bus, local bus, quantum bus and/or another type of bus that can employ one or more bus architectures. One or more of these examples of bus 205 can be employed.

In one or more embodiments, the waveform instruction system 202 can be coupled (e.g., communicatively, electrically, operatively, optically and/or like function) to one or more external systems (e.g., a non-illustrated electrical output production system, one or more output targets, an output target controller and/or the like), sources and/or devices (e.g., classical and/or quantum computing devices, communication devices and/or like devices), such as via a network. In one or more embodiments, one or more of the components of the waveform instruction system 202 and/or of the non-limiting system 200 can reside in the cloud, and/or can reside locally in a local computing environment (e.g., at a specified location(s)).

In addition to the processor 206 and/or memory 204 described above, the waveform instruction system 202 can comprise one or more computer and/or machine readable, writable and/or executable components and/or instructions that, when executed by processor 206, can provide performance of one or more operations defined by such component(s) and/or instruction(s).

Turning now to the additional components of the waveform instruction system 202 (e.g., obtaining component 212, instruction component 214 and/or transmitting component 216), generally, the waveform instruction system 202 can perform one or more operations to facilitate waveform generation by the waveform generator 110 of the quantum system 101.

The obtaining component 212 can receive, locate, find, determine and/or otherwise obtain a quantum job request 124 or other instruction for executing a waveform, such as in response to requested operation of a quantum circuit or quantum gate. Such instruction can originate from a user entity of the waveform instruction system 202 and/or from external to the waveform instruction system 202. The instruction can be employed by the control subsystem 217 to generate a waveform instruction for controlling/directing generation of a waveform.

As used herein, a control subsystem 217 can comprise the instruction component 214 and the transmitting component 216 and a waveform subsystem 157 can comprise the memory 156 and processing unit 154.

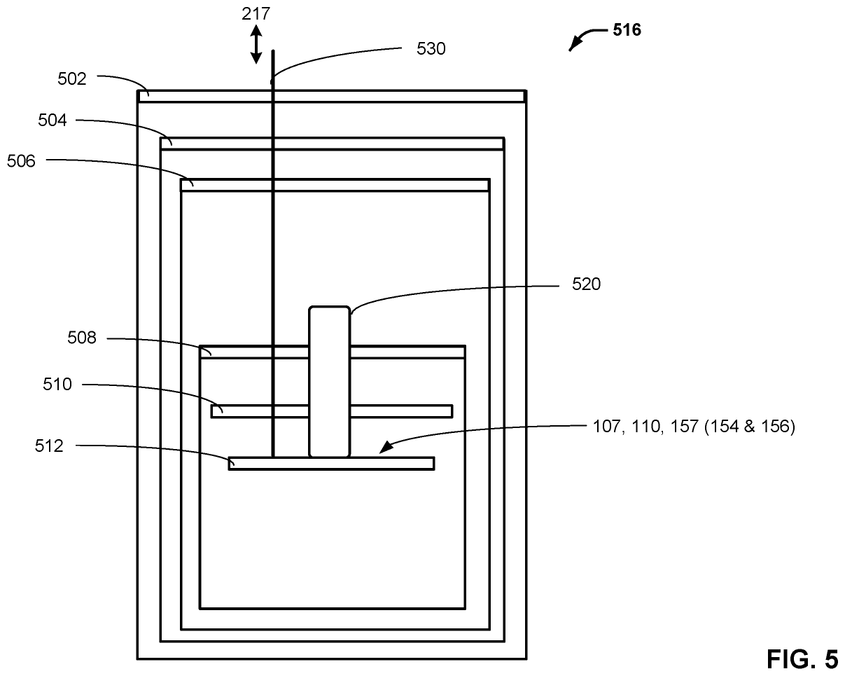

The control subsystem 217 can be communicatively coupled to the waveform subsystem 157 by any suitable wire, cable and/or other signal transfer medium (e.g., signal transfer medium 530 of FIG. 5). Depending on a size, density, material, dimension and/or other property of the signal transfer medium, transmission speed and/or volume can be limited along the signal transfer medium. As a result, and as mentioned above and throughout the specification, transmission of full instructions, including full parameter determinations, along such signal transfer medium can result in an inability to receive instructions by the waveform generator 110 in time necessary to generate back-to-back waveforms and/or to perform other time-sensitive quantum gate processes, such as in connection with a dynamic circuit. That is, bandwidth along the signal transfer medium can be limited and thus use of pre-loading of one or more waveform definition aspects into a memory 156 associated with the waveform generator 110, such as in the form of a play table 250, can allow for more rapid and efficient waveform generation.

For example, as mentioned above, issuance of such instruction, using the one or more embodiments described herein can allow for about 4 bits to about 10 bits of information to be sent to a respective waveform subsystem to direct the recall of the one or more waveform definition aspects for a quantum gate execution. Differently, using existing techniques, and/or during pre-loading using the one or more embodiments described herein, a full waveform instruction being sent to the waveform subsystem between waveform generations can account for at least 100 bits to 150 bits of information.

Accordingly, in response to the obtained instruction, the instruction component 214 can prepare an instruction for operating a quantum gate by directing generation of a waveform, and the transmitting component 216 can transmit one or more instructions from the control subsystem 217 to the waveform subsystem 157, such as along a signal transfer medium 530, as described above.

The instruction component 214 can comprise any suitable hardware and/or software for generating and directing sending of instructions for generating a waveform. The transmitting component 216 can comprise any suitable hardware and/or software suitable for transmitting one or more instructions along the signal transfer medium 530.

The instruction can be for directing execution of a quantum gate requested for current execution or the instruction can be for pre-loading the memory 156 for a future waveform generation. The instructions can comprise data/metadata that directly including a waveform definition aspect and/or direct to a waveform definition aspect.

The waveform definition aspects are the entries that are accessed by the processing unit 154 associated with the waveform generator 110, from the memory 156, to thereby facilitate generation of a waveform by the waveform generator 110.

Each waveform definition aspect can comprise at least one type of aspect, such as waveform parameter (e.g., frequency, phase, amplitude, envelope and/or duration, without being limited thereto), a partial waveform parameter, a calculation for generating a waveform parameter, a direction to obtain a waveform parameter, a callup function for obtaining a waveform parameter (e.g., from the memory 156), and/or a static or non-static function call for obtaining a waveform parameter (e.g., from the memory 156).

In one or more embodiments, these waveform definition aspects can be stored in the form of a play table or a playlist, with a playlist generally being a form of a play table as will be described below.

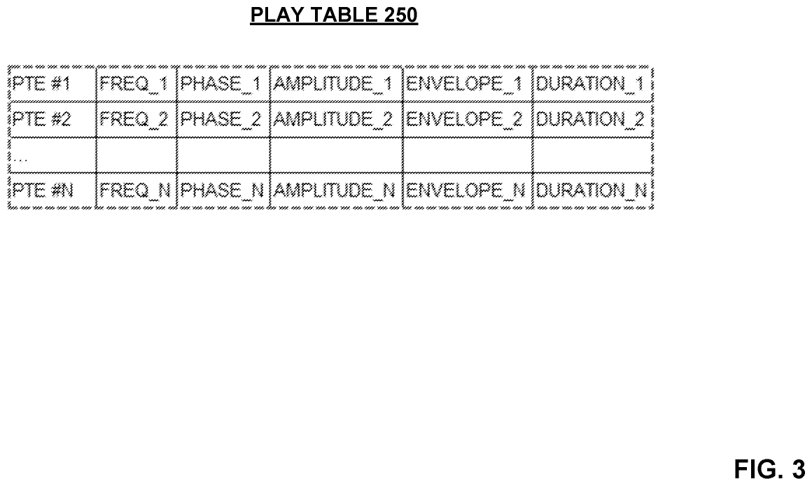

A play table can comprise a table, registry, log, list, matrix and/or other form of data arrangement. For example, turning briefly to FIG. 3, a play table 250 can be defined as having one or more play table entries (PTEs) which each can comprise one or more waveform definition aspects (e.g., a set of parameters that characterize a waveform). Different waveform definition aspects of a same PTE can comprise different types of aspects, e.g., a waveform, calculation, callup function, etc.

A waveform can be generated by the waveform generator 110 based on one or more instructions (e.g., quantum job request 124 or otherwise) specifying one or more PTE's directly or specifying one or more separate waveform definition entries. For example, reference to a PTE in the play table 250 can allow for reference to the associated waveform definition entries in the play table 250 by the processing unit 154. The processing unit 154 can transmit and/or a component of the waveform generator 110 can obtain one or more parameters corresponding to the associated waveform definition entries for subsequently being employed for parameterization of a waveform to be generated by the waveform generator 110, such as a numerically controlled oscillator.

In a case where a first play table comprises one or more callup functions and/or static or non-static function calls, such callup functions and/or function calls can refer to/direct to a secondary play table comprising waveform definition aspects being one or more full or partial waveform parameters and/or calculations for generating one or more waveform parameters.

As but one example, the play table 250 can comprise 1 to N PTEs. PTE #1 is illustrated as comprising five different waveform definition entries, which each are a parameter. PTE #2 is illustrated as comprising five different waveform definition entries, which each are a parameter. Although, in one or more other embodiments, one or more of the waveform definition entries instead can be a callup function, function call and/or otherwise.

In one or more embodiments, the waveform definition entries of a play table entry (PTE) can comprise and/or correspond to less than all parameters needed by the waveform generator 100 to generate a waveform. In such case, one or more instructions transmitted to the wave player subsystem can refer to another play table entry or to one or more other waveform definition aspects which can correspond to one or more additional parameters needed by the waveform generator 110 to generate the waveform.

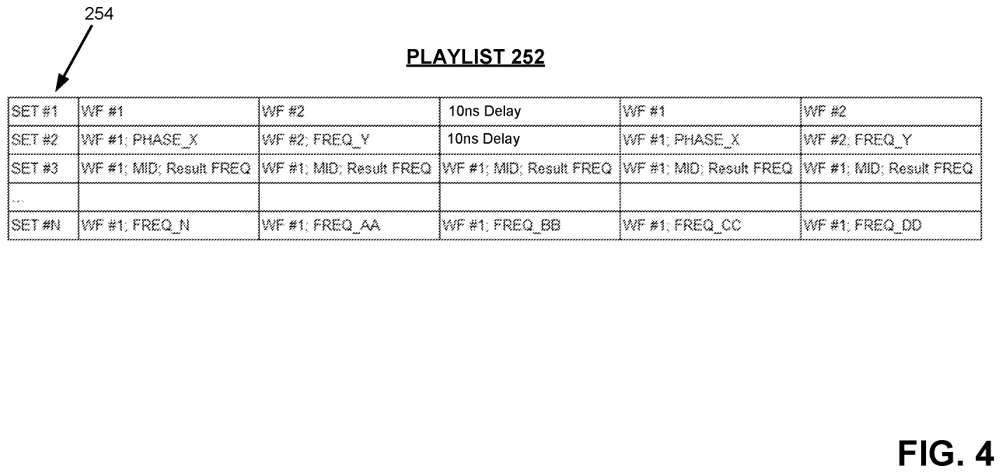

Turning next to FIG. 4, a playlist, such as the playlist 252, can be a type of play table. As illustrated at playlist 252, a playlist set can correspond to instructions to perform a sequence of waveforms, in a particular order, with or without a delay (also specified), and/or with or without one or more parameter modifications. A playlist can be a useful storage and reference aspect in the case of running numerous waveforms in repeated sequence, such as during a calibration, during repeating of shots for an experiment, and/or the like, without being limited thereto.

A playlist 252 can comprise one or more identifiers 254 (e.g., SET #1, SET #2, etc.). Each identifier 254 reference and/or correspond to a plurality of waveform definition aspects. More particularly, each identifier 254 can reference and/or correspond to one or more play table entries (e.g., WF #1, WF #2, etc.), and each play table entry of the one or more play table entries can reference and/or correspond to a plurality of waveform definition aspects. That is, each identifier 254 can define an order in which the one or more play table entries are to be employed (e.g., by the processing unit 154 and/or waveform generator 110). For example, playlist identifier SET #1 references, in order, WF #1, WF #2, a delay, WF #1 and WF #2. Each of WF #1 and WF #2 can themselves be identifiers that can reference one or more other play tables. For example WF #1 can refer to PTE #1 of play table 250 and WF #2 can refer to PTE #2 of play table 250.

A parameter modification can be provided in a playlist set of waveform definition aspects, such as corresponding to a callup function or as a reference to another play table or waveform definition aspect. Such parameter modification can be efficient as compared to referral to a completely different waveform (thus also necessitating loading and storage of one or more parameters for such completely different waveform). That is, for example, playlist identifier SET #2 at playlist 252 indicates that a first waveform (WF) to generate is WF #1, but with Phase_X. Specification of Phase_X can be a reference to a parameter (e.g., waveform definition aspect) at yet another play table or can be held in other short term or long term memory associated with the processing unit 154. Indeed, using in SET #2 a reference to WF #1 with a modified parameter can employ less data storage space than defining numerous different waveforms each similar to WF #1 but with only one or more parameter alterations as compared to WF #1 (e.g., WF #1-A, WF #1-B, . . . . WF #1-N each specifying only one, two or a few parameters different from one another).

A playlist identifier 254 also can refer to one or more waveform definition aspects comprising an instruction for performing and/or using a mid-circuit measurement (e.g., MID). In such case, the processing unit 154 can be communicatively coupled to the quantum operation component 103 and/or readout electronics 112. For example, playlist identifier SET #3 comprises a set of five waveform definition aspects that each include a mid-circuit measurement. For example, SET #3 can correspond to performance of WF #1 with a mid-circuit measurement being taken and resulting in a FREQ. In one or more embodiments, the FREQ can be employed as a default frequency for the next waveform to be generated, based on one or more instructions embedded in and/or referred to by the playlist 252 or identifier 254, or can be directed by another instruction transmitted from the control subsystem 217 to the wave player subsystem 157.

Turning next to FIG. 5 and to the disposition (e.g., location) of the waveform subsystem 157 and the waveform generator 110 with which the waveform subsystem 157 is associated, these components can be disposed in a cryogenic environment, in one or more embodiments.

For example, turning to FIG. 5, the quantum system 101 can comprise a cryostat 516 for providing the cryogenic environment 117. The cryostat 516 can comprise a set of plates (e.g., plates) that together with a plurality of external and internal shields (e.g., shields) can define a plurality of internal thermally insulated sections. Where a first internal thermally insulated section is internal to a second internal thermally insulated section, the second internal thermally insulated section can be at least partially thermally insulated to, and retain a cooler temperature than, the first internal thermally insulated section. While not shown, the cryostat 516 can comprise a set of heat exchangers, valves, feed lines and return lines.

The plates can comprise a cold plate 510 and a mixing chamber plate 512 each at least partially cooled by a dilution refrigeration unit 520. Quantum components, such as component comprising and/or comprised by physical qubits (e.g., 107A, 107B and/or 107C), can be disposed at the cold plate 510 and/or the mixing chamber plate 512. At least a portion of each of the processing unit 154, memory 156 and waveform generator 110 can be disposed in the cryostat 516. In one example, the waveform subsystem 157 can be comprised in an area of the cryostat 516 cooled to about 10K to about 4K. In another example, as illustrated at FIG. 5, the waveform subsystem 157 can be comprised in an area of the cryostat 516 cooled by the dilution refrigeration unit 520. Put another way, the waveform subsystem 157 can be generally adjacent one or more physical qubits and/or at least a portion of the waveform generator 110, within the cryostat 516. This can allow for rapid transmission between the waveform subsystem 157 and the waveform generator 110. Also as illustrated, the signal transfer medium 530 extends into the cryostat 516 allowing for communication between the waveform subsystem 157 and the control subsystem 217.

As previously mentioned above, the instruction component 214 can prepare an instruction (a) for storing of a waveform definition aspect and/or (b) for directing generation of a waveform. Put another way, the waveform instruction system 202 can respectively direct generation and/or transmission of (a) waveform setup instruction 122 or (b) a quantum job request 124.

Turning first to generation of a waveform setup instruction 122 for loading the memory 156 that is associated with the waveform generator 110, the instruction component 214 can prepare instructions for sending to the processing unit 154 and memory 156 that are associated with the waveform generator 110. For example, the instructions, including data/metadata, for loading the memory 156 can be prepared by the instruction component 214, transmitted by the transmitting component 216, obtained (e.g., received) by the processing unit 154, and stored by the memory 156.

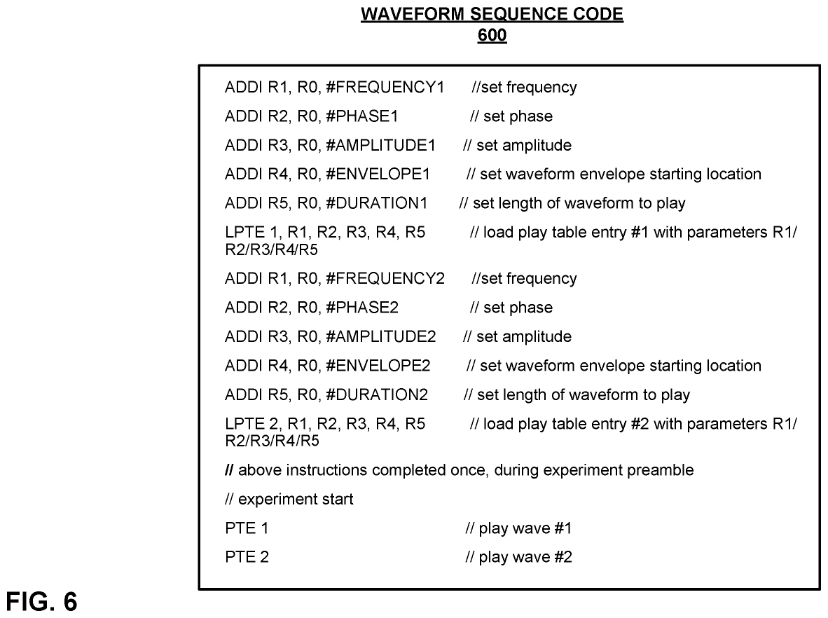

For example, referring to the exemplary waveform sequence code 600 of FIG. 6, one or more loading instructions can comprise setting various parameters for a play wave #1, including loading one or more of the various parameters to a play table entry (PTE) #1, such as PTE #1 of the play table 250 and/or loading the play table entry. That is, these instructions (lines 1-6) can be pre-loading instructions performed prior to a shot or at a preamble of a shot. Alternatively, where a gate time of a gate being executed allows, these instructions (lines 1-6) can be issued during execution of the shot.

As shown, the exemplary waveform sequence code 600 of FIG. 6 further can comprise instructions (e.g., lines 7-12) for setting various parameters for a plurality of additional play waves, such as a play wave #2, including loading one or more of the various parameters to a play table entry (PTE) #2, such as PTE #2 of the play table 250.

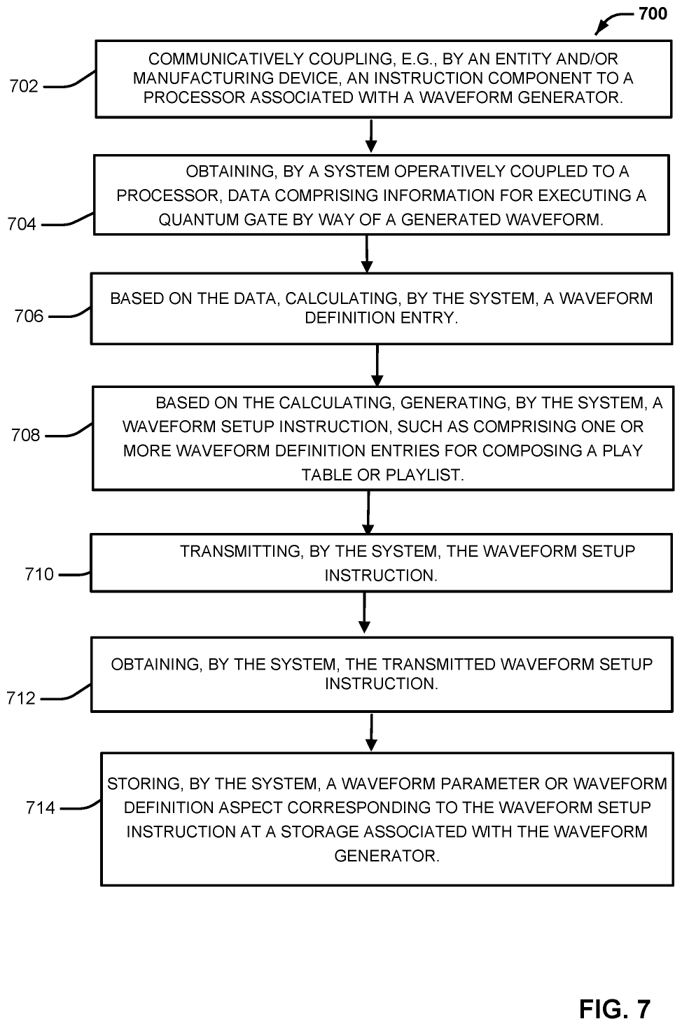

Next, FIG. 7 illustrates a flow diagram of an example, non-limiting method 700 that can provide a process load a waveform definition aspect for subsequent use by a waveform generator, such as of a quantum system, in accordance with one or more embodiments described herein, such as the non-limiting 200 of FIG. 2. While the non-limiting method 700 is described relative to the non-limiting system 200 of FIG. 2, the non-limiting method 700 can be applicable also to other systems described herein, such as the non-limiting system 100 of FIG. 1. Repetitive description of like elements and/or processes employed in respective embodiments is omitted for sake of brevity.

At 702, the non-limiting method 700 can comprise communicatively coupling, e.g., by an entity and/or manufacturing device, an instruction component (e.g., instruction component 214) to a processor associated with a waveform generator (e.g., processing unit 154 associated with the waveform generator 110).

At 704, the non-limiting method 700 can comprise obtaining, by the system (e.g., obtaining component 212 of the waveform instruction system 202) data comprising information for executing a quantum gate by way of a generated waveform.

At 706, the non-limiting method 700 can comprise, based on the data, calculating, by the system (e.g., instruction component 214) a waveform definition aspect (e.g., waveform parameter).

At 708, the non-limiting method 700 can comprise, based on the calculating, generating, by the system (e.g., instruction component 214) a waveform setup instruction (e.g., waveform setup instruction 122), such as comprising one or more waveform definition aspects for composing a play table (e.g., play table 250) or playlist (e.g., playlist 252).

At 710, the non-limiting method 700 can comprise transmitting, by the system (e.g., transmitting component 216), the waveform setup instruction.

At 712, the non-limiting method 700 can comprise obtaining, by the system (e.g., quantum operation component 103 of quantum system 101), the transmitted waveform setup instruction.

At 714, the non-limiting method 700 can comprise storing, by the system (e.g., processing unit 154), a waveform parameter or waveform definition aspect corresponding to the waveform setup instruction at a storage associated with the waveform generator (e.g., memory 156). In one or more embodiments, the storing can comprise inserting a waveform definition aspect of the waveform setup instruction into a playlist or play table.

Direction turns next to instructing generation of a waveform based on a waveform definition aspect at least partially pre-loaded to the memory 156. Based on the process of loading a waveform definition aspect to the memory 156, the waveform definition aspect can be employed by the processing unit 154 to finalize waveform definition for waveform generation by the waveform generator 110. For example, turning to FIG. 6, to operate a quantum gate via generation of a waveform, the instruction component 214 can direct the transmitting component 216 to provide one or more instructions by way of one or more quantum job requests 124 to the quantum system 101, such as to the processing unit 154. As illustrated at FIG. 6, these one or more instructions can be those of the exemplary waveform sequence code 600. As illustrated, these instructions can comprise, after loading parameters at one or more play tables and/or playlists, merely instructing play of a waveform definition aspect at a play table and/or playlist. In this case, the waveform definition aspect can refer to PTE #1 for generating a play wave #1, where the PTE #1 waveform definition aspect contains a plurality of other waveform definition aspects (e.g., defining frequency, phase, amplitude, waveform envelope starting location, and/or duration of waveform).

In one or more embodiments, as mentioned above, back-to-back instructions can be provided for generation of more than one waveform. As mentioned, this can be the case at the beginning of a shot (e.g., preamble), during a quantum gate execution providing a gate time corresponding to the time necessary to send the back-to-back instructions, and/or the like. In one or more cases, during the preamble of a shot, the memory 156 can retain the parameters for these waveforms at least until generation of the waveforms by the waveform generator 110. Accordingly, the instructions of the exemplary waveform sequence code 600 further can comprise playing a play wave #2 based on a play table entry (PTE) #2, such as PTE #2 of the play table 250.

One or more additional/alternative instructions can comprise instructions to play the waves back-to-back during execution of the shot.

One or more additional/alternative instructions can comprise instructions to play a play wave (e.g., play wave #1 or play wave #2) but with one or more parameter modifications (e.g., an override; e.g., using one or more parameters that are different from those loaded at a play table and/or playlist. Such instruction can include the parameter to use, but not necessarily instruct replacement of the parameter directly at the play table/playlist. That is, the instruction need not comprise a write instruction to the memory 156. A parameter modification can be useful in various situations, such as for execution of conditional phase gates where overriding a parameter, or for execution of dynamic circuit.

In summary, in use, the play table, such as the play table 250 of FIG. 4, or the playlist, such as the playlist 252 of FIG. 5, can allow software, e.g., employed by the instruction component 214 to specify one or more waveform definition aspects and then generally point to, reference, and/or direct to the entry at the play table for the waveform generator 110 (e.g., for the waveform subsystem 157, such as the processing unit 154). As mentioned above and throughout the specification, this can allow for waveforms to be generated back-to-back without delay or gaps therebetween. That is, during the duration of one waveform, an instruction can be transmitted into the cryogenic environment 117 to the waveform generator 110 and the next waveform can be initialized to thereby follow (such as immediately follow) the previous waveform duration.

This can be made possible because the amount of information needed to generate the waveform (e.g., at minimum only that needed to direct to the play table entry) can be minimized, thus minimizing the amount of information to transfer into the cryogenic environment 117 between the control subsystem 217 and the waveform subsystem 157. Put another way, there can be separation of software control from waveform generation since the amount of information to transfer to the waveform generation is greatly reduced as compared to existing frameworks. As a result, the waveform generation, including the access to a play table, can be performed close to the qubit being operated upon, e.g., inside the cryogenic environment.

In an example, relative to the PTE #1 of play table 250, each waveform definition aspect can refer to a parameter comprised by about 16 to about 32 bits of information, meaning that over about 100 bits to about 150 bits of information would be transferred per play wave generation instruction. Even using a wide bus as the signal transfer medium 530, which allows for about 10 bits to about 20 bits of data transfer at a time, which requires many wires going into a dilution refrigerated environment, and which does not scale well when adding multiple waveform generators in a single dilution refrigerated environment, sending that amount of information can take approximately 10 to approximately 15 transfer cycles. Accordingly, sending these parameters ahead of time and storing them as waveform definition aspects in a play table or playlist can instead allow for about 4 bits to about 10 bits of information to be sent to the waveform subsystem 157 to direct the recall of the one or more waveform definition aspects for quantum gate execution.

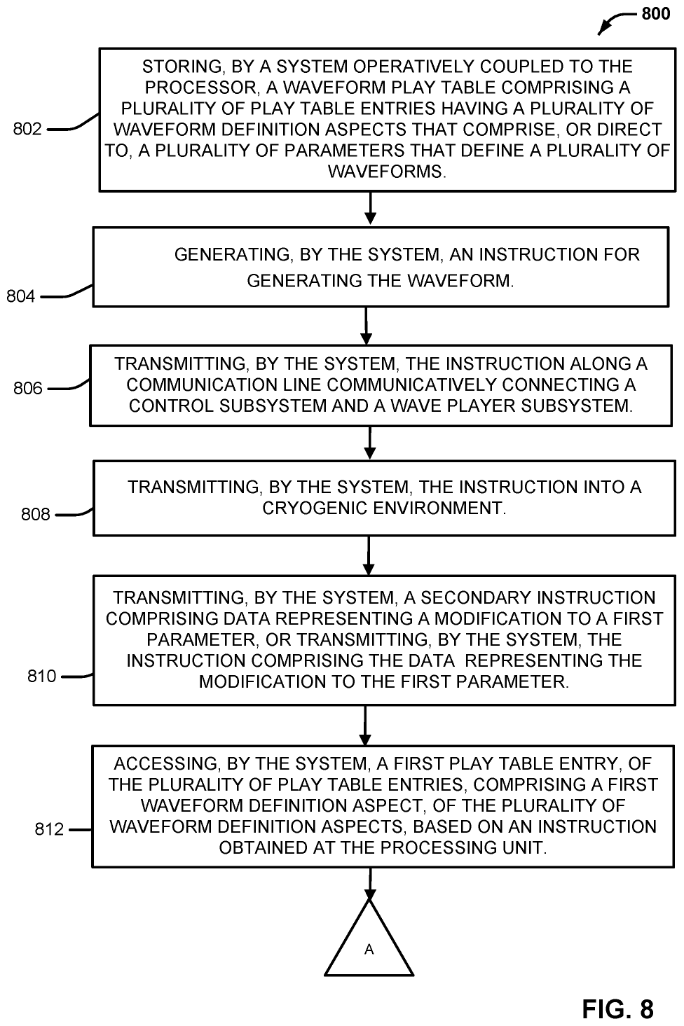

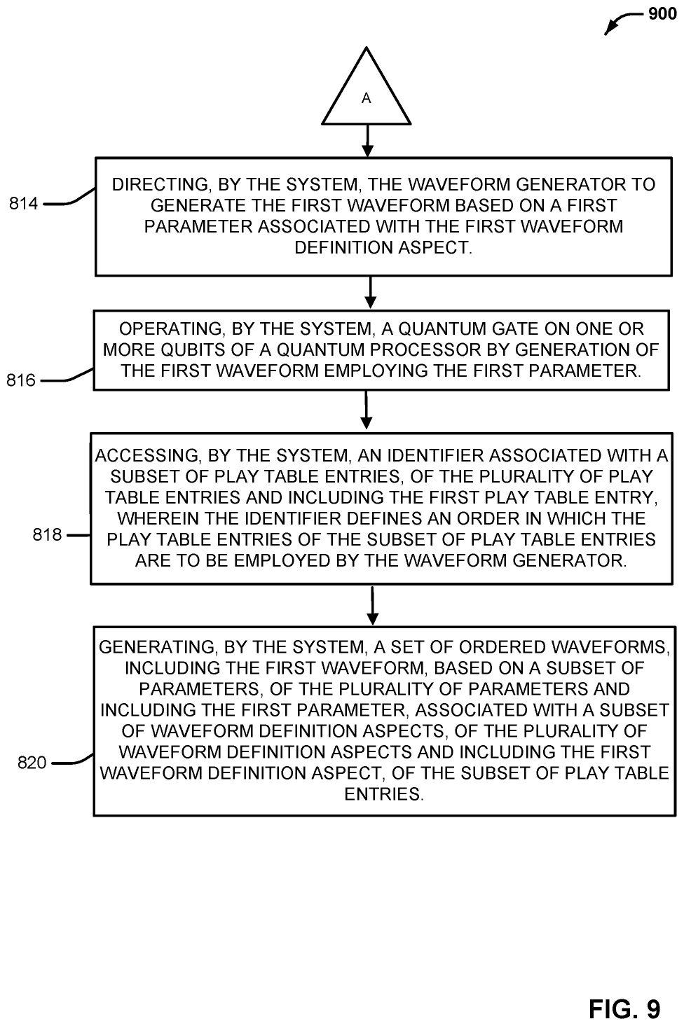

Next, in additional summary, FIGS. 8 and 9 illustrate a flow diagram of an example, non-limiting method 800 that can provide a process to generate a waveform by a waveform generator, such as of a quantum system, in accordance with one or more embodiments described herein, such as the non-limiting 200 of FIG. 2. While the non-limiting method 800 is described relative to the non-limiting system 200 of FIG. 2, the non-limiting method 800 can be applicable also to other systems described herein, such as the non-limiting system 100 of FIG. 1. Repetitive description of like elements and/or processes employed in respective embodiments is omitted for sake of brevity.

At 802, the non-limiting method 800 can comprise storing, by a system operatively coupled to the processor (e.g., memory 156 of the quantum system 101), a waveform play table comprising a plurality of play table entries having a plurality of waveform definition aspects that comprise, or direct to, a plurality of parameters that define a plurality of waveforms.

At 804, the non-limiting method 800 can comprise generating, by the system (e.g., instruction component 214 of the waveform instruction system 202), an instruction for generating the waveform.

At 806, the non-limiting method 800 can comprise transmitting, by the system (e.g., transmitting component 216), the instruction along a communication line communicatively connecting a control subsystem (e.g., the control subsystem 217 comprising the instruction component 214 and the transmitting component 216 of the waveform instruction system 202) and a wave player subsystem (e.g., the wave player subsystem 157 comprising the memory 156 and processing unit 154 associated with the waveform generator 110).

At 808, the non-limiting method 800 can comprise transmitting, by the system (e.g., transmitting component 216), the instruction into a cryogenic environment (e.g., cryogenic environment 117 of the quantum system 101).

At 810, the non-limiting method 800 can comprise transmitting, by the system (e.g., transmitting component 216), a secondary instruction comprising data representing a modification to a first parameter, or can comprise transmitting, by the system (e.g., transmitting component 216), the instruction comprising the data representing the modification to the first parameter.

At 812, the non-limiting method 800 can comprise accessing, by the system (e.g., processing unit 154), a first play table entry, of the plurality of play table entries, comprising a first waveform definition aspect, of the plurality of waveform definition aspects, based on an instruction obtained at the processing unit.

At 814, the non-limiting method 800 can comprise directing, by the system (e.g., processing unit 154), the waveform generator to generate the first waveform based on a first parameter associated with the first waveform definition aspect.

At 816, the non-limiting method 800 can comprise operating, by the system (e.g., waveform generator 110), a quantum gate on one or more qubits of a quantum processor by generation of the first waveform employing the first parameter.

At 818, the non-limiting method 800 can comprise accessing, by the system (e.g., processing unit 154), an identifier associated with a subset of play table entries, of the plurality of play table entries and including the first play table entry, wherein the identifier defines an order in which the play table entries of the subset of play table entries are to be employed by the wave form generator.

At 820, the non-limiting method 800 can comprise generating, by the system (e.g., waveform generator 110), a set of ordered waveforms, including the first waveform, based on a subset of parameters, of the plurality of parameters and including the first parameter, associated with a subset of waveform definition aspects, of the plurality of waveform definition aspects and including the first waveform definition aspect, of the subset of play table entries.

In addition, one or more practical considerations can apply to use of one or more embodiments discussed above. For example, conditional reset of a qubit can be performed in real-time; T1 decay between readout and reset pulse can increase reset error; other qubits not being reset, still can deteriorate via T1 decay and T2 decoherence; T1 and T2 can be on the order of 50˜100 us for superconducting transmon qubits; conditional reset cycle time (from sending measurement pulse to end of reset) can be about 1 μs; and hardware can be controlled to read out qubit state and control conditional pulse, without software intervention.

### ADDITIONAL SUMMARY

For simplicity of explanation, the computer-implemented and non-computer-implemented methodologies provided herein are depicted and/or described as a series of acts. It is to be understood that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented and non-computer-implemented methodologies in accordance with the described subject matter. In addition, the computer-implemented and non-computer-implemented methodologies could alternatively be represented as a series of interrelated states via a state diagram or events. Additionally, the computer-implemented methodologies described hereinafter and throughout this specification are capable of being stored on an article of manufacture for transporting and transferring the computer-implemented methodologies to computers. The term article of manufacture, as used herein, is intended to encompass a computer program accessible from any computer-readable device or storage media.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

Where description indicates a process as taking place at a classical system or a quantum system, it is noted that in one or more other embodiments, such process can take place, at least partially, at the other of the classical system or the quantum system, where suitable and/or where such other system is configured to perform the process.

In summary, one or more systems, devices, computer program products and/or computer-implemented methods of use provided herein relate to a process to rapidly generate waveforms for quantum operations, the process employing separation of waveform software control from waveform generation control. An exemplary wave player system can comprise a waveform generator, a memory associated with the waveform generator, wherein the memory stores a waveform play table comprising a plurality of play table entries having a plurality of waveform definition aspects that comprise, or direct to, a plurality of parameters that define a plurality of waveforms, and a processing unit associated with the waveform generator, wherein the processing unit accesses a first play table entry, of the plurality of play table entries, comprising a first waveform definition aspect, of the plurality of waveform definition aspects, based on an instruction obtained at the processing unit.

An advantage of any one or more of the above-indicated embodiments can be, relative to a cryogenic-based waveform generator, performance of overhead, including waveform parameter definition and/or quantum circuit waveform instruction, majoratively using hardware/software disposed external to the cryogenic environment of a quantum device. In this way, reduced data generation and data transfer can be provided within the cryogenic environment, based on use of loaded waveform definition aspects at a memory that is cryogenically disposed and associated with the waveform generator. This further can result in reduced power requirement and reduced heat generation within the cryogenic environment, such as by a corresponding processing unit disposed within the cryogenic environment and associated with the waveform generator.

Another advantage of the above-indicated embodiments can be separation of waveform software control from waveform generation control for generating the waveforms. This can allow for reduced data necessary to be transmitted into a cryogenic environment to the waveform generator to cause generation of a waveform during quantum circuit operation. That is, loading of the memory associated with the waveform generator with waveform definition aspects can be performed separate from quantum circuit operation.

Subsequently, during quantum circuit operation, overhead of setting parameters between waveform generations can be performed external to the cryogenic environment absent transfer of any, or at least of large quantities of, data into the cryogenic environment for the parameter determination. As a result, waveform generation in the cryogenic environment can be based on low-data-volume instructions transmitted from a software controller external to the cryogenic environment to the processor associated with the waveform generator, while employing the loaded waveform definition aspects. That is, the reduced instruction transmission time correlates with reduced quantum gate operation times available in the currently rapidly evolving domain of quantum device operation. This further can result in, relative to a quantum application, operation of an increased number of shots (e.g., quantum circuit executions) within a given time defining qubit coherency for those one or more qubits of the quantum being employed (e.g., being operated upon by the waveform generator). That is, gap-time between waveform generations can be limited and/or altogether eliminated.

Indeed, in view of the one or more embodiments described herein, a practical application of the systems, computer-implemented methods and/or computer program products described herein can be ability to correlate time necessary to define, instruct operation of, and generate a waveform for operating a quantum gate within a quantum gate operation time of a gate already in operation, such as in connection with a prior-initiated waveform generation. That is, when operating a quantum circuit comprising a dynamic circuit, employing back-to-back waveform generations, or otherwise necessitating rapid obtaining of waveform instruction at a cryogenic waveform generator, the one or more embodiments provided herein can improve functioning of a quantum computer (or of a combination of a classical computer and a quantum computer) comprising the waveform generator. Improvement can be by way of allowing for formation of instructions for generation of one or more waveforms within a low time range correlating to continuingly reduced quantum gate operation times. Additional improvement can be by way of reduced power generation for waveform generation within a cryogenic environment. Even further improvement can comprise additional operations, e.g., shots, being able to be performed within a given time (e.g., within a given qubit coherence time prior to degeneration of the coherent state—e.g., decoherence). This can result in reduced overhead for calculation due to use of same qubits for additional operations within a same time window.

Furthermore, one or more embodiments described herein can be employed in a real-world system based on the disclosed teachings. For example, one or more embodiments described herein can function with a quantum system that can receive as input a quantum job request comprising a quantum source code for execution comprising one or more operations as described herein, and that can measure a real-world qubit state of one or more qubits, such as superconducting qubits, of the quantum system, by executing the quantum source code at some level of the quantum system.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can be, in one or more embodiments, inherently and/or inextricably tied to computer technology and cannot be implemented outside of a computing environment. For example, one or more processes performed by one or more embodiments described herein can more efficiently, and even more feasibly, provide program and/or program instruction execution, such as relative to quantum circuit execution, and/or to cryogenic environment-based waveform generation, as compared to existing systems and/or techniques. Systems, computer-implemented methods and/or computer program products providing performance of these processes are of great utility in the fields of quantum circuit operation and/or waveform generation more generally and cannot be equally practicably implemented in a sensible way outside of a computing environment.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively automatically perform quantum circuit encoding, load a quantum register, perform quantum calculations, generate a waveform and/or measure a state of qubit as the one or more embodiments described herein can provide these processes. Moreover, neither can the human mind nor a human with pen and paper conduct one or more of these processes, as conducted by one or more embodiments described herein.

In one or more embodiments, one or more of the processes described herein can be performed by one or more specialized computers (e.g., a specialized processing unit, a specialized classical computer, a specialized quantum computer, a specialized hybrid classical/quantum system and/or another type of specialized computer) to execute defined tasks related to the one or more technologies describe above. One or more embodiments described herein and/or components thereof can be employed to solve new problems that arise through advancements in technologies mentioned above, employment of quantum computing systems, cloud computing systems, computer architecture and/or another technology.

One or more embodiments described herein can be fully operational towards performing one or more other functions (e.g., fully powered on, fully executed and/or another function) while also performing one or more of the one or more operations described herein.

To provide additional summary, a listing of embodiments and features thereof is next provided.

A wave player system, comprising: a waveform generator; a memory associated with the waveform generator, wherein the memory stores a waveform play table comprising a plurality of play table entries having a plurality of waveform definition aspects that comprise, or direct to, a plurality of parameters that define a plurality of waveforms; and a processing unit associated with the waveform generator, wherein the processing unit accesses a first play table entry, of the plurality of play table entries, comprising a first waveform definition aspect, of the plurality of waveform definition aspects, based on an instruction obtained at the processing unit.

The wave player system of the preceding paragraph, wherein the processing unit further directs the waveform generator to generate a first waveform based on a first parameter associated with the first waveform definition aspect.

The wave player system of any preceding paragraph, further comprising: an instruction component of a control subsystem that generates the instruction; and a transmitting component of the control subsystem that transmits the instruction along a communication line communicatively connecting the control subsystem and a wave player subsystem comprising the memory and the processing unit associated with the waveform generator.

The wave player system of any preceding paragraph, wherein the wave play subsystem is disposed within a cryogenic environment, and wherein the control subsystem is disposed external to the cryogenic environment.

The wave player system of any preceding paragraph, wherein the transmitting component, via direction of the instruction component, further transmits a secondary instruction comprising data representing a modification to the first parameter, or wherein the transmitting component, via direction of the instruction component, transmits the instruction comprising the data representing the modification to the first parameter.

The wave player system of any preceding paragraph, wherein the waveform generator, employing the first parameter, operates a quantum gate on one or more qubits of a quantum processor by generation of the first waveform.

The wave player system of any preceding paragraph, wherein an identifier associated with a subset of play table entries, of the plurality of play table entries and including the first play table entry, defines an order in which the play table entries of the subset of play table entries are to be employed by the waveform generator, wherein the instruction directs access to the identifier by the processing unit, and wherein the access results in generation, by the waveform generator, of a set of ordered waveforms, including the first waveform, based on a subset of parameters, of the plurality of parameters and including the first parameter, associated with a subset of waveform definition aspects, of the plurality of waveform definition aspects and including the first waveform definition aspect, of the subset of play table entries.

A computer-implemented method, comprising: storing, by a system operatively coupled to the processor, at a memory associated with a waveform generator, a waveform play table comprising a plurality of play table entries having a plurality of waveform definition aspects that comprise, or direct to, a plurality of parameters that define a plurality of waveforms; and accessing, by a processing unit of the system that is associated with the waveform generator a first play table entry, of the plurality of play table entries, comprising a first waveform definition aspect, of the plurality of waveform definition aspects, based on an instruction obtained at the processing unit.

The computer-implemented method of the preceding paragraph, further comprising: directing, by the processing unit, the waveform generator to generate a first waveform based on a first parameter associated with the first waveform definition aspect.

The computer-implemented method of any preceding paragraph, further comprising:
generating, by a control subsystem, the instructions; and transmitting, by the control subsystem, the instruction along a communication line communicatively connecting the control subsystem and a wave player subsystem comprising the memory and processing unit associated with the waveform generator.

The computer-implemented method of any preceding paragraph, wherein the wave play subsystem is disposed within a cryogenic environment, and wherein the control subsystem is disposed external to the cryogenic environment.

The computer-implemented method of any preceding paragraph, further comprising: transmitting, by the control subsystem, a secondary instruction comprising data representing a modification to the first parameter, or transmitting, by the control subsystem, the instruction comprising the data representing the modification to the first parameter.

The computer-implemented method of any preceding paragraph, further comprising: operating a quantum gate on one or more qubits of a quantum processor by generation of the first waveform employing the first parameter.

The computer-implemented method of any preceding paragraph, wherein an identifier associated with a subset of play table entries, of the plurality of play table entries and including the first play table entry, defines an order in which the play table entries of the subset of play table entries are to be employed by the waveform generator, wherein the instruction directs access to the identifier by the processing unit, and wherein the access results in generation, by the waveform generator, of a set of ordered waveforms, including the first waveform, based on a subset of parameters, of the plurality of parameters and including the first parameter, associated with a subset of waveform definition aspects, of the plurality of waveform definition aspects and including the first waveform definition aspect, of the subset of play table entries.

A computer program product facilitating a process to generate a waveform, the computer program product comprising a computer readable storage medium having program instructions embodied therewith, the program instructions executable by a processor to cause the processor to: store, by the processor, at a memory associated with a waveform generator, a waveform play table comprising a plurality of play table entries having a plurality of waveform definition aspects that comprise, or direct to, a plurality of parameters that define a plurality of waveforms; and access, by an additional processing unit of the system, that is associated with the waveform generator a first play table entry, of the plurality of play table entries, comprising a first waveform definition aspect, of the plurality of waveform definition aspects, based on an instruction obtained at the processing unit.

The computer program product of the preceding paragraph, wherein the program instructions are further executable by the process to cause the processor to: direct, by the additional processing unit, the waveform generator to generate a first waveform based on a first parameter associated with the first waveform definition aspect.

The computer program product of any preceding paragraph, wherein the program instructions are further executable by the process to cause the processor to: generate, by a control subsystem comprising the processor, the instructions; and transmit, by the processor of the control subsystem, the instruction along a communication line communicatively connecting the control subsystem and a wave player subsystem comprising the memory and processing unit associated with the waveform generator.

The computer program product of any preceding paragraph, wherein the wave play subsystem is disposed within a cryogenic environment, and wherein the control subsystem is disposed external to the cryogenic environment.

The computer program product of any preceding paragraph, wherein the program instructions are further executable by the process to cause the processor to: transmit, by the processor of the control subsystem, a secondary instruction comprising data representing a modification to the first parameter, or transmit, by the processor of the control subsystem, the instruction comprising the data representing the modification to the first parameter.

The computer program product of any preceding paragraph, wherein an identifier associated with a subset of play table entries, of the plurality of play table entries and including the first play table entry, defines an order in which the play table entries of the subset of play table entries are to be employed by the waveform generator, wherein the instruction directs access to the identifier by the processing unit, and wherein the access results in generation, by the waveform generator, of a set of ordered waveforms, including the first waveform, based on a subset of parameters, of the plurality of parameters and including the first parameter, associated with a subset of waveform definition aspects, of the plurality of waveform definition aspects and including the first waveform definition aspect, of the subset of play table entries.

### Computing Environment Description

Turning next to FIG. 10, a detailed description is provided of additional context for the one or more embodiments described herein at FIGS. 1-9.

FIG. 10 and the following discussion are intended to provide a brief, general description of a suitable computing environment 1000 in which one or more embodiments described herein at FIGS. 1-9 can be implemented. For example, various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), crasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1000 contains an example of an environment for the execution of at least some of the computer code involved in performing the inventive methods, such as translation of an original source code based on a configuration of a target system by the quantum operation execution code 1080. In addition to block 1080, computing environment 1000 includes, for example, computer 1001, wide area network (WAN) 1002, end user device (EUD) 1003, remote server 1004, public cloud 1005, and private cloud 1006. In this embodiment, computer 1001 includes processor set 1010 (including processing circuitry 1020 and cache 1021), communication fabric 1011, volatile memory 1012, persistent storage 1013 (including operating system 1022 and block 1080, as identified above), peripheral device set 1014 (including user interface (UI), device set 1023, storage 1024, and Internet of Things (IoT) sensor set 1025), and network module 1015. Remote server 1004 includes remote database 1030. Public cloud 1005 includes gateway 1040, cloud orchestration module 1041, host physical machine set 1042, virtual machine set 1043, and container set 1044.

COMPUTER 1001 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1030. As is well understood in the art of computer technology, and depending upon the technology, performance of a computer-implemented method may be distributed among multiple computers and/or between multiple locations. On the other hand, in this presentation of computing environment 1000, detailed discussion is focused on a single computer, specifically computer 1001, to keep the presentation as simple as possible. Computer 1001 may be located in a cloud, even though it is not shown in a cloud in FIG. 10. On the other hand, computer 1001 is not required to be in a cloud except to any extent as may be affirmatively indicated.

PROCESSOR SET 1010 includes one, or more, computer processors of any type now known or to be developed in the future. Processing circuitry 1020 may be distributed over multiple packages, for example, multiple, coordinated integrated circuit chips. Processing circuitry 1020 may implement multiple processor threads and/or multiple processor cores. Cache 1021 is memory that is located in the processor chip package(s) and is typically used for data or code that should be available for rapid access by the threads or cores running on processor set 1010. Cache memories are typically organized into multiple levels depending upon relative proximity to the processing circuitry. Alternatively, some, or all, of the cache for the processor set may be located “off chip.” In some computing environments, processor set 1010 may be designed for working with qubits and performing quantum computing.

Computer readable program instructions are typically loaded onto computer 1001 to cause a series of operational steps to be performed by processor set 1010 of computer 1001 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1021 and the other storage media discussed below. The program instructions, and associated data, are accessed by processor set 1010 to control and direct performance of the inventive methods. In computing environment 1000, at least some of the instructions for performing the inventive methods may be stored in block 1080 in persistent storage 1013.

COMMUNICATION FABRIC 1011 is the signal conduction paths that allows the various components of computer 1001 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 1012 is any type of volatile memory now known or to be developed in the future. Examples include dynamic type random access memory (RAM) or static type RAM. Typically, the volatile memory is characterized by random access, but this is not required unless affirmatively indicated. In computer 1001, the volatile memory 1012 is located in a single package and is internal to computer 1001, but, alternatively or additionally, the volatile memory may be distributed over multiple packages and/or located externally with respect to computer 1001.

PERSISTENT STORAGE 1013 is any form of non-volatile storage for computers that is now known or to be developed in the future. The non-volatility of this storage means that the stored data is maintained regardless of whether power is being supplied to computer 1001 and/or directly to persistent storage 1013. Persistent storage 1013 may be a read only memory (ROM), but typically at least a portion of the persistent storage allows writing of data, deletion of data and re-writing of data. Some familiar forms of persistent storage include magnetic disks and solid state storage devices. Operating system 1022 may take several forms, such as various known proprietary operating systems or open source Portable Operating System Interface type operating systems that employ a kernel. The code included in block 1080 typically includes at least some of the computer code involved in performing the inventive methods.

PERIPHERAL DEVICE SET 1014 includes the set of peripheral devices of computer 1001. Data communication connections between the peripheral devices and the other components of computer 1001 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1023 may include components such as a display screen, speaker, microphone, wearable devices (such as goggles and smart watches), keyboard, mouse, printer, touchpad, game controllers, and haptic devices. Storage 1024 is external storage, such as an external hard drive, or insertable storage, such as an SD card. Storage 1024 may be persistent and/or volatile. In some embodiments, storage 1024 may take the form of a quantum computing storage device for storing data in the form of qubits. In embodiments where computer 1001 is required to have a large amount of storage (for example, where computer 1001 locally stores and manages a large database) then this storage may be provided by peripheral storage devices designed for storing very large amounts of data, such as a storage area network (SAN) that is shared by multiple, geographically distributed computers. IoT sensor set 1025 is made up of sensors that can be used in Internet of Things applications. For example, one sensor may be a thermometer and another sensor may be a motion detector.

NETWORK MODULE 1015 is the collection of computer software, hardware, and firmware that allows computer 1001 to communicate with other computers through WAN 1002. Network module 1015 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1015 are performed on the same physical hardware device. In other embodiments (for example, embodiments that utilize software-defined networking (SDN)), the control functions and the forwarding functions of network module 1015 are performed on physically separate devices, such that the control functions manage several different network hardware devices. Computer readable program instructions for performing the inventive methods can typically be downloaded to computer 1001 from an external computer or external storage device through a network adapter card or network interface included in network module 1015.

WAN 1002 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1003 is any computer system that is used and controlled by an end user (for example, a customer of an enterprise that operates computer 1001) and may take any of the forms discussed above in connection with computer 1001. EUD 1003 typically receives helpful and useful data from the operations of computer 1001. For example, in a hypothetical case where computer 1001 is designed to provide a recommendation to an end user, this recommendation would typically be communicated from network module 1015 of computer 1001 through WAN 1002 to EUD 1003. In this way, EUD 1003 can display, or otherwise present, the recommendation to an end user. In some embodiments, EUD 1003 may be a client device, such as thin client, heavy client, mainframe computer, desktop computer and so on.

REMOTE SERVER 1004 is any computer system that serves at least some data and/or functionality to computer 1001. Remote server 1004 may be controlled and used by the same entity that operates computer 1001. Remote server 1004 represents the machine(s) that collect and store helpful and useful data for use by other computers, such as computer 1001. For example, in a hypothetical case where computer 1001 is designed and programmed to provide a recommendation based on historical data, then this historical data may be provided to computer 1001 from remote database 1030 of remote server 1004.

PUBLIC CLOUD 1005 is any computer system available for use by multiple entities that provides on-demand availability of computer system resources and/or other computer capabilities, especially data storage (cloud storage) and computing power, without direct active management by the scale. The direct and active management of the computing resources of public cloud 1005 is performed by the computer hardware and/or software of cloud orchestration module 1041. The computing resources provided by public cloud 1005 are typically implemented by virtual computing environments that run on various computers making up the computers of host physical machine set 1042, which is the universe of physical computers in and/or available to public cloud 1005. The virtual computing environments (VCEs) typically take the form of virtual machines from virtual machine set 1043 and/or containers from container set 1044. It is understood that these VCEs may be stored as images and may be transferred among and between the various physical machine hosts, either as images or after instantiation of the VCE. Cloud orchestration module 1041 manages the transfer and storage of images, deploys new instantiations of VCEs and manages active instantiations of VCE deployments. Gateway 1040 is the collection of computer software, hardware, and firmware that allows public cloud 1005 to communicate through WAN 1002.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1006 is similar to public cloud 1005, except that the computing resources are only available for use by a single enterprise. While private cloud 1006 is depicted as being in communication with WAN 1002, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1005 and private cloud 1006 are both part of a larger hybrid cloud.

### Additional Closing Information

The embodiments described herein can be directed to one or more of a system, a method, an apparatus and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a superconducting storage device and/or any suitable combination of the foregoing. A non-exhaustive list of more specific examples of the computer readable storage medium can also include the following: a portable computer diskette, a hard disk, a random access memory (RAM), a read-only memory (ROM), an crasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, is not to be construed as being transitory signals per se, such as radio waves and/or other freely propagating electromagnetic waves, electromagnetic waves propagating through a waveguide and/or other transmission media (e.g., light pulses passing through a fiber-optic cable), and/or electrical signals transmitted through a wire.

Computer readable program instructions described herein can be downloaded to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a stand-alone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field-programmable gate arrays (FPGA) and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function(s). In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter has been described above in the general context of computer-executable instructions of a computer program product that runs on a computer and/or computers, those skilled in the art will recognize that the one or more embodiments herein also can be implemented in combination with one or more other program modules. Generally, program modules include routines, programs, components, data structures and/or the like that perform particular tasks and/or implement particular abstract data types. Moreover, the aforedescribed computer-implemented methods can be practiced with other computer system configurations, including single-processor and/or multiprocessor computer systems, mini-computing devices, mainframe computers, as well as computers, hand-held computing devices (e.g., PDA, phone), microprocessor-based or programmable consumer and/or industrial electronics and/or the like. The illustrated aspects can also be practiced in distributed computing environments in which tasks are performed by remote processing devices that are linked through a communications network. However, one or more, if not all aspects of the one or more embodiments described herein can be practiced on stand-alone computers. In a distributed computing environment, program modules can be located in both local and remote memory storage devices.

As used in this application, the terms “component,” “system,” “platform,” “interface,” and/or the like, can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter described herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit and/or device comprising, but not limited to, single-core processors; single-processors with software multithread execution capability; multi-core processors; multi-core processors with software multithread execution capability; multi-core processors with hardware multithread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular and quantum-dot based transistors, switches and/or gates, in order to optimize space usage and/or to enhance performance of related equipment. A processor can be implemented as a combination of computing processing units.

Herein, terms such as “store,” “storage,” “data store,” data storage,” “database,” and substantially any other information storage component relevant to operation and functionality of a component are utilized to refer to “memory components,” entities embodied in a “memory,” or components comprising a memory. Memory and/or memory components described herein can be cither volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory and/or nonvolatile random access memory (RAM) (e.g., ferroelectric RAM (FeRAM). Volatile memory can include RAM, which can act as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein are intended to include, without being limited to including, these and/or any other suitable types of memory.

What has been described above includes mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

The descriptions of the various embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A wave player system, comprising:
a waveform generator;
a memory associated with the waveform generator,
wherein the memory stores a waveform play table comprising a plurality of play table entries having a plurality of waveform definition aspects that comprise, or direct to, a plurality of parameters that define a plurality of waveforms; and
a processing unit associated with the waveform generator,
wherein the processing unit accesses a first play table entry, of the plurality of play table entries, comprising a first waveform definition aspect, of the plurality of waveform definition aspects, based on an instruction obtained at the processing unit.

2. The wave player system of claim 1, wherein the processing unit further directs the waveform generator to generate a first waveform based on a first parameter associated with the first waveform definition aspect.

3. The wave player system of claim 1, further comprising:
an instruction component of a control subsystem that generates the instruction; and
a transmitting component of the control subsystem that transmits the instruction along a communication line communicatively connecting the control subsystem and a wave player subsystem comprising the memory and the processing unit associated with the waveform generator.

4. The wave player system of claim 3,
wherein the wave play subsystem is disposed within a cryogenic environment, and
wherein the control subsystem is disposed external to the cryogenic environment.

5. The wave player system of claim 3,
wherein the transmitting component, via direction of the instruction component, further transmits a secondary instruction comprising data representing a modification to the first parameter, or
wherein the transmitting component, via direction of the instruction component, transmits the instruction comprising the data representing the modification to the first parameter.

6. The wave player system of claim 2,
wherein the waveform generator, employing the first parameter, operates a quantum gate on one or more qubits of a quantum processor by generation of the first waveform.

7. The wave player system of claim 1,
wherein an identifier associated with a subset of play table entries, of the plurality of play table entries and including the first play table entry, defines an order in which the play table entries of the subset of play table entries are to be employed by the waveform generator,
wherein the instruction directs access to the identifier by the processing unit, and
wherein the access results in generation, by the waveform generator, of a set of ordered waveforms, including the first waveform, based on a subset of parameters, of the plurality of parameters and including the first parameter, associated with a subset of waveform definition aspects, of the plurality of waveform definition aspects and including the first waveform definition aspect, of the subset of play table entries.

8. A computer-implemented method, comprising:
storing, by a system operatively coupled to the processor, at a memory associated with a waveform generator, a waveform play table comprising a plurality of play table entries having a plurality of waveform definition aspects that comprise, or direct to, a plurality of parameters that define a plurality of waveforms; and
accessing, by a processing unit of the system that is associated with the waveform generator a first play table entry, of the plurality of play table entries, comprising a first waveform definition aspect, of the plurality of waveform definition aspects, based on an instruction obtained at the processing unit.

9. The computer-implemented method of claim 8, further comprising:
directing, by the processing unit, the waveform generator to generate a first waveform based on a first parameter associated with the first waveform definition aspect.

10. The computer-implemented method of claim 8, further comprising:
generating, by a control subsystem, the instructions; and
transmitting, by the control subsystem, the instruction along a communication line communicatively connecting the control subsystem and a wave player subsystem comprising the memory and processing unit associated with the waveform generator.

11. The computer-implemented method of claim 10,
wherein the wave play subsystem is disposed within a cryogenic environment, and
wherein the control subsystem is disposed external to the cryogenic environment.

12. The computer-implemented method of claim 10, further comprising:
transmitting, by the control subsystem, a secondary instruction comprising data representing a modification to the first parameter, or
transmitting, by the control subsystem, the instruction comprising the data representing the modification to the first parameter.

13. The computer-implemented method of claim 9, further comprising:
operating a quantum gate on one or more qubits of a quantum processor by generation of the first waveform employing the first parameter.

14. The computer-implemented method of claim 8,
wherein an identifier associated with a subset of play table entries, of the plurality of play table entries and including the first play table entry, defines an order in which the play table entries of the subset of play table entries are to be employed by the waveform generator,
wherein the instruction directs access to the identifier by the processing unit, and
wherein the access results in generation, by the waveform generator, of a set of ordered waveforms, including the first waveform, based on a subset of parameters, of the plurality of parameters and including the first parameter, associated with a subset of waveform definition aspects, of the plurality of waveform definition aspects and including the first waveform definition aspect, of the subset of play table entries.

15. A computer program product facilitating a process to generate a waveform, the computer program product comprising a computer readable storage medium having program instructions embodied therewith, the program instructions executable by a processor to cause the processor to:
store, by the processor, at a memory associated with a waveform generator, a waveform play table comprising a plurality of play table entries having a plurality of waveform definition aspects that comprise, or direct to, a plurality of parameters that define a plurality of waveforms; and
access, by an additional processing unit of the system, that is associated with the waveform generator a first play table entry, of the plurality of play table entries, comprising a first waveform definition aspect, of the plurality of waveform definition aspects, based on an instruction obtained at the processing unit.

16. The computer program product of claim 15, wherein the program instructions are further executable by the process to cause the processor to:
direct, by the additional processing unit, the waveform generator to generate a first waveform based on a first parameter associated with the first waveform definition aspect.

17. The computer program product of claim 15, wherein the program instructions are further executable by the process to cause the processor to:
generate, by a control subsystem comprising the processor, the instructions; and
transmit, by the processor of the control subsystem, the instruction along a communication line communicatively connecting the control subsystem and a wave player subsystem comprising the memory and processing unit associated with the waveform generator.

18. The computer program product of claim 17,
wherein the wave play subsystem is disposed within a cryogenic environment, and
wherein the control subsystem is disposed external to the cryogenic environment.

19. The computer program product of claim 17, wherein the program instructions are further executable by the process to cause the processor to:
transmit, by the processor of the control subsystem, a secondary instruction comprising data representing a modification to the first parameter, or
transmit, by processor of the control subsystem, the instruction comprising the data representing the modification to the first parameter.

20. The computer program product of claim 15,
wherein an identifier associated with a subset of play table entries, of the plurality of play table entries and including the first play table entry, defines an order in which the play table entries of the subset of play table entries are to be employed by the waveform generator,
wherein the instruction directs access to the identifier by the processing unit, and
wherein the access results in generation, by the waveform generator, of a set of ordered waveforms, including the first waveform, based on a subset of parameters, of the plurality of parameters and including the first parameter, associated with a subset of waveform definition aspects, of the plurality of waveform definition aspects and including the first waveform definition aspect, of the subset of play table entries.
